(19) United States
(12) Patent Application Publication
(10) Pub. No.: US 2008/0023792 A1
(43) Pub. Date: Jan. 31, 2008

(54) FILLER CAPACITOR WITH A MULTIPLE CELL HEIGHT

(75) Inventors: Tien-Yueh Liu, Hsinchu City (TW); Hsiu-Chen Peng, Hsinchu City (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: MEDIATEK INC., Hsin-Chu (TW)

(21) Appl. No.: 11/460,641

(22) Filed: Jul. 28, 2006

(51) Int. Cl. H01L 29/00

(52) U.S. Cl. 257/532

(57) ABSTRACT

Embodiments of the invention provide a layout architecture for a standard cell integrated circuit having an array of logic cells. A plurality of first power rails is above a substrate, each of the first power rails being coupled to a power supply and extending across the logic cells. Adjacent first power rails are coupled to different voltage supplies. A filler capacitor is positioned beneath three or more adjacent first power rails and coupled to first and second voltage supplies. The filler capacitor comprises a first MOS capacitor formed with a first gate overlapping a first base in a first active region, the first gate coupled to the first voltage supply and the first base coupled to the second voltage supply. A middle first power rail of the three or more adjacent first power rails extends across the first active region.

### BACKGROUND OF THE INVENTION

1. Field of the Invention

The invention generally relates to cell-based integrated circuits, and in particular, to an improved standard cell architecture providing high capacitance for filler capacitors.

2. Description of the Related Art

Standard cell design technology has been developed as a method of quickly and efficiently designing integrated circuits. Standard cell technology is characterized by its fixed set of predesigned basic cells, such as NAND, NOR, flip-flops, multiplexers, counters and the like, preferably configured for dense placement and efficient signal routing. Basic cells needed for a design are simply selected and their interconnections are determined, and design is automatically placed and routed using software tools. Typically the selected basic cells are arrayed on the integrated circuit in rows and columns, interconnected by conductive traces to form complex circuits or logic structures.

FIG. 1 shows a basic cell 100 with power rails, 102 and 104, running along the top and bottom edges. Typically, power rails 102 and 104 are coupled to low and high voltage power sources, supplying the power for basic cell 100. After placement and routing, individual basic cells in a cell row, such as basic cells 11 0, 11 2, 114, 116, and 118 shown in FIG. 2, are placed adjacent to one another so that the power rails 102 and 104 run continuously from one end of the cell row to the other. In the event that there is a gap 120 in the cell row, the power rail is made to be continuous either by use of a filler cell or by routing a wire through the gap.

Certain filler cells are filler capacitors, each substantially being a capacitor coupled between two power rails at the top and bottom: of the filler capacitor. Filler capacitors in gaps in cell rows stabilize power voltages for the basic cells in the same cell row and ease power surge or noise interference at those basic cells.

### BRIEF SUMMARY OF THE INVENTION

Embodiments of the invention provide a layout architecture for a standard cell integrated circuit having an array of logic cells. A plurality of first power rails are above a substrate, each coupled to a power supply and extending across the logic cells. Adjacent first power rails are coupled to different voltage supplies. A filler capacitor beneath three or more adjacent first power rails is coupled to first and second voltage supplies. The filler capacitor comprises first and second MOS capacitors. The first MOS capacitor is formed with a first gate overlapping a first base in a first active region, the first gate coupled to the first voltage supply and the first base coupled to the second voltage supply. The second MOS capacitor is formed with a second gate overlapping a second base in a second active region, the second gate coupled to the second voltage supply and a second base coupled to the first voltage supply. A middle first power rail of the three or more adjacent first power rails extends across the first or second active region.

Embodiments of the invention further provide a method for forming a layout architecture. A circuit netlist is provided. An electronic design automation tool performs placement and routing according to the circuit netlist to place logic cell layouts on a floor plan of an integrated circuit. The logic cell layouts are arranged into cell rows. The floor plan introduces first power rails, each of the first power rails being coupled to a power supply and extending along the cell rows and across the logic cell layouts. Adjacent first power rails are coupled to different voltage supplies. On the floor plan, unused area is retrieved, unoccupied by the logic cell layouts, spanning two or more of the cell rows, and located under three or more first power rails. A filler capacitor layout is placed in the unused area, where the filler capacitor layout introduces a MOS capacitor formed with a first gate overlapping a first base in a first active region, the first gate coupled to a first voltage supply and the first base coupled to a second voltage supply. A middle first power: rail of the three or more adjacent first power rails extends across the first active region.

Embodiments of the invention further provide a layout architecture for a standard cell integrated circuit having an array of logic cells. A plurality of first power rails is above a substrate, each coupled to a power supply and extending across the logic cells. Adjacent first power rails are coupled to different voltage supplies. A filler capacitor is positioned beneath three or more adjacent first power rails and coupled to first and second voltage supplies. The filler capacitor comprises a first MOS capacitor formed with a first gate overlapping a first base in a first active region, the first gate coupled to the first voltage supply and the first base coupled to the second voltage supply. A middle first power rail of the three or more adjacent first power rails extends across the first active region.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 exemplifies a basic cell with power rails running along the top and bottom edge of the basic cell;

FIG. 2 shows a row of individual basic cells;

FIG. 3 is a circuit illustration of a single-sized filler capacitor;

FIG. 4 shows a cell layout of the single-sized filler capacitor 200 in FIG. 3;

FIG. 5 shows the layout of a single-sized filler capacitor in a cell row and an upside-down single-sized filler capacitor in an adjacent cell row;

FIG. 6 introduces a layout of a double-sized filler capacitor that spans two adjacent cell rows;

FIG. 7a introduces a layout of another double-sized filler capacitor that spans two adjacent cell rows;

FIG. 7b shows two stacked single-sized filler capacitors having poly gates and active regions substantially separated by the middle power rail VSS;

FIGS. 8a and 8b show the layouts of two triple-sized filler capacitors, each spanning three consecutive cell rows;

FIG. 9 shows a summarized step flow according to embodiments of the invention;

FIG. 10 exemplifies a circuit netlist connecting two NOTs, a NAND and a PLL;

FIG. 11 shows a floor plan after placement and routing;

FIG. 12 details step 806 in FIG. 11;

FIG. 13 depicts that an unused, rectangular area spanning three cell rows is retrieved from the floor plan;

FIG. 14 shows two unused, rectangular area, each spanning two cell rows, are retrieved; and

FIG. 15 shows one unused, rectangular area spanning with only one cell row height is retrieved and may be filled in by a single-sized filler capacitor or a filler well.

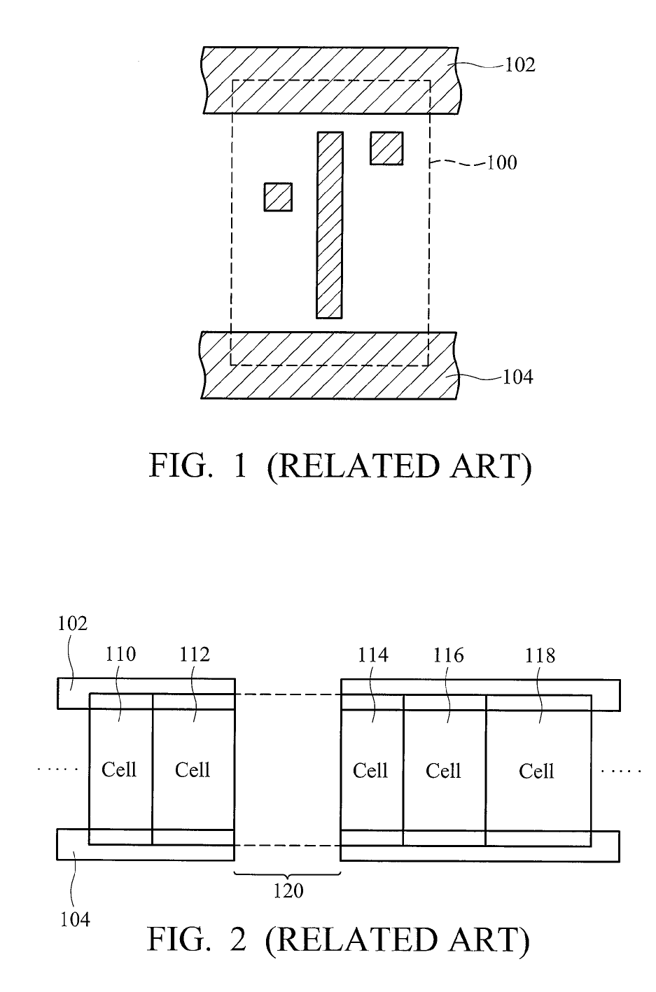

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

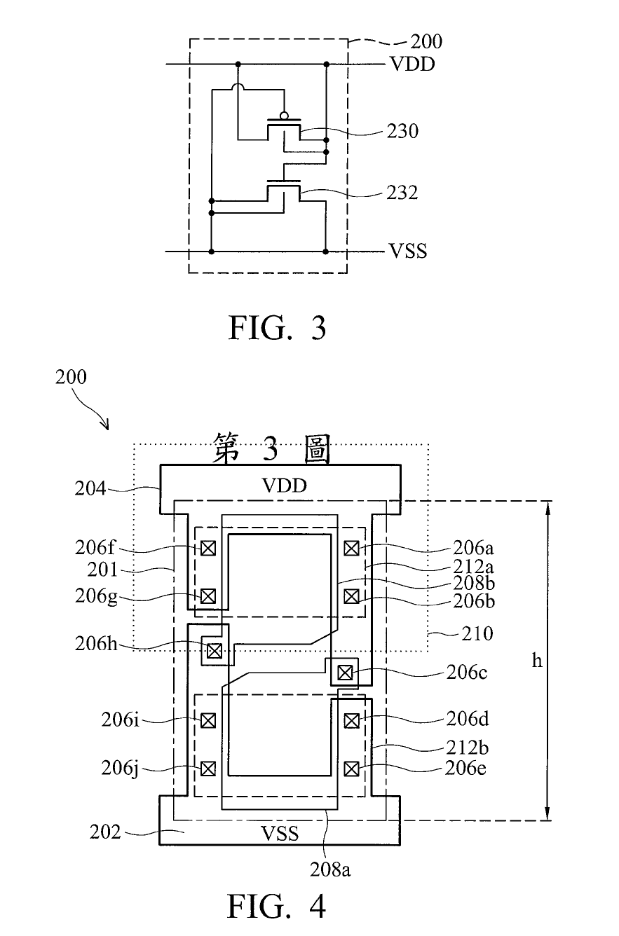

FIG. 3 is a circuit illustration of a single-sized filler capacitor 200. As shown in FIG. 3, single-sized filler capacitor 200 consists of NMOS and PMOS capacitors, respectively numbered 232 and 230. PMOS capacitor 230 is a PMOS transistor with a gate coupled to power rail VSS and source/drains coupled to power rail VDD. The base of the PMOS transistor is also coupled to power rail VDD. When normally powered, the channel under the gate of the PMOS transistor is in inverse accumulation such that the source/drains of the PMOS transistor act as a top plate of the PMOS capacitor and the gate acts as a bottom plate of the PMOS capacitor. Between the top and bottom plates of the PMOS capacitor is the gate insulator of the PMOS transistor. Similar to PMOS capacitor 230, NMOS capacitor 232 is a NMOS transistor with a gate coupled to power rail VDD and source/drains and a base all coupled to power rail VDD. The source/drains of the NMOS transistor act as a bottom plate of the NMOS capacitor and the gate acts as a top plate of the NMOS capacitor while the top and bottom plates are isolated by the gate insulator of the NMOS transistor.

FIG. 4 shows a cell layout of the single-sized filler capacitor 200 in FIG. 3. A cell boundary 201 defines the area and size of single-sized filler capacitor 200. Power rail VDD, of a metal conductor of a metal layer, runs along the top edge of the single-sized filler capacitor 200. Power rail VSS, of a metal conductor of the same metal layer as power rail VDD, runs along the bottom edge of the single-sized filler capacitor 200. The top half portion of single-sized filler capacitor 200 has a N well 210 coupled to power rail VDD via a well contact inside either single-sized filler capacitor 200 or another nearby basic cell. The bottom half portion of single-sized filler capacitor 200 has a P well/substrate coupled to power rail VSS by means known in the art. Typically, an N well and a P well/substrate are used to form PMOS and NMOS transistors therein, respectively.

Active region 212a and poly plate 208b together define the location of a PMOS transistor. The gate of the PMOS transistor is the area of poly plate 208b overlapping active region 212a, and the source/drains are the areas in active region 212a exposed and separated by poly plate 208b. Gate and source/drain definition is applicable to not only the PMOS transistor but also the NMOS transistor at the bottom half portion of single-sized filler capacitor 200. Thus, active region 212b and poly plate 208a define the location of the NMOS transistor. As shown in FIG. 4, metal conductors as well as contacts provide required bias for gates and source/drains of the PMOS and NMOS transistors shown in FIG. 3. Contacts 206a-206c and 206f-206g couple the gate of the NMOS transistor and the source/drains of the PMOS transistor to power rail VDD. Likewise, contacts 206d-206e and 206h-206j couple the gate of the PMOS transistor and the source/drains of the NMOS transistor to power rail VSS.

Single-sized filler capacitor 200 in FIG. 4 is available for a cell row having power rail VDD at its top and power rail VSS at its bottom. If power rails VDD and VSS are interchanged, an upside-down filler single-sized filler capacitor may be utilized.

If a gap in a cell row is wide enough, single-sized filler capacitor 200 of varying width can fill the gap, such that power rails VDD and VSS as well as N well 210 and P well/substrate continue from one end of the cell row to the other. If the gap is narrower than the minimum width required for single-sized filler capacitor 200, a filler well may continue power rails VDD and VSS, and N well 210 and P well/substrate along a cell row.

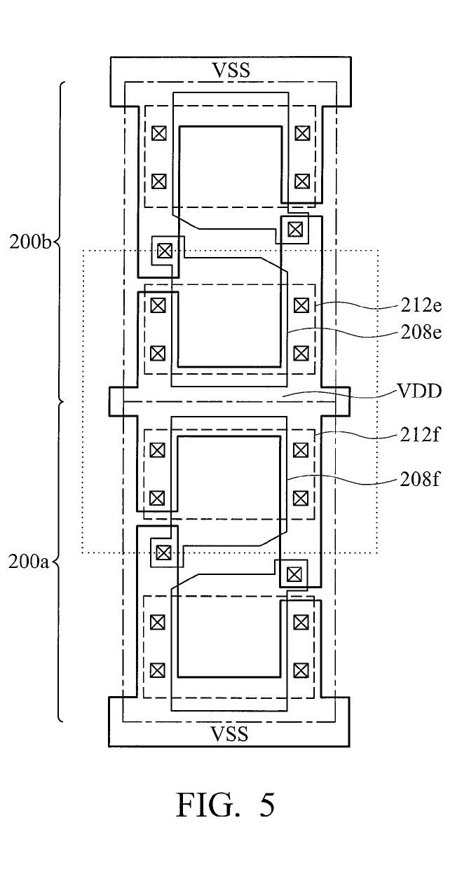

FIG. 5 shows the layout of a single-sized filler capacitor 200a stacked on an upside-down single-sized filler capacitor 200b in an adjacent cell row. As shown, single-sized filler capacitors 200a and 200b are of the same width, and share a common power rail VDD and a common N well.

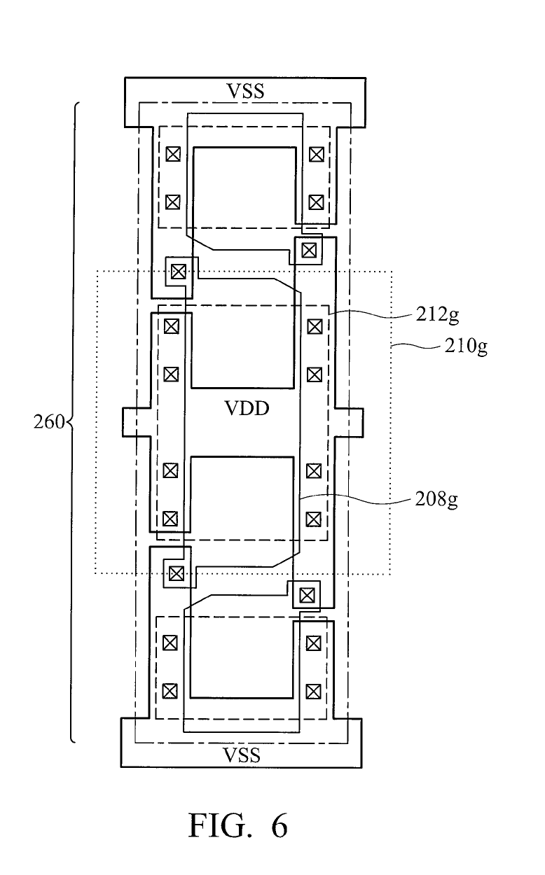

FIG. 6 shows a layout of a double-sized filler capacitor 260 spanning two adjacent cell rows. Three power rails VSS, VDD and VSS extend across double-sized filler capacitor 260. The middle power rail VDD extends across poly gate 208g and active region 212g, together forming a PMOS capacitor beneath the middle power rail VDD. As shown in FIG. 6, the poly gate 208g, an electrode plate of the PMOS capacitor, is coupled to power rail VSS while N well 210g, the other electrode plate of the PMOS capacitor, is coupled to power rail VDD. Two NMOS capacitors are formed in the top and bottom portions of double-sized filler capacitor 260, each with a poly gate coupled to power rail VDD and a P well/substrate coupled to power rail VSS. If each of the two adjacent cell rows has a fixed height, double-sized filler capacitor 260 has two row heights, and the midpoint of double-sized filler capacitor 260 is under the middle power rail VDD.

Double-sized filler capacitor 260 in FIG. 6 is similar to the combination of the stacked single-sized filler capacitors 200a and 200b in FIG. 5, except that poly plate 208g and active region 212g of FIG. 6 span from the bottom half portion of the top cell row to the top half portion of the bottom cell row while, as shown in FIG. 5, poly plates 208e and 208f are separated as are active regions 212e and 212f. In comparison with the stacked single-sized filler capacitors 200a and 200b in FIG. 5, double-sized filler capacitor 260 in FIG. 6 provides higher capacitance since extra capacitance is gained by converting the field isolation area in FIG. 5 under a middle power rail VDD to a portion of a PMOS capacitor. As margins required for a single-sized filler capacitor to isolate its poly plate and active region from its cell boundary increase, capacitance percentage obtained by a double-sized filler capacitor increases accordingly.

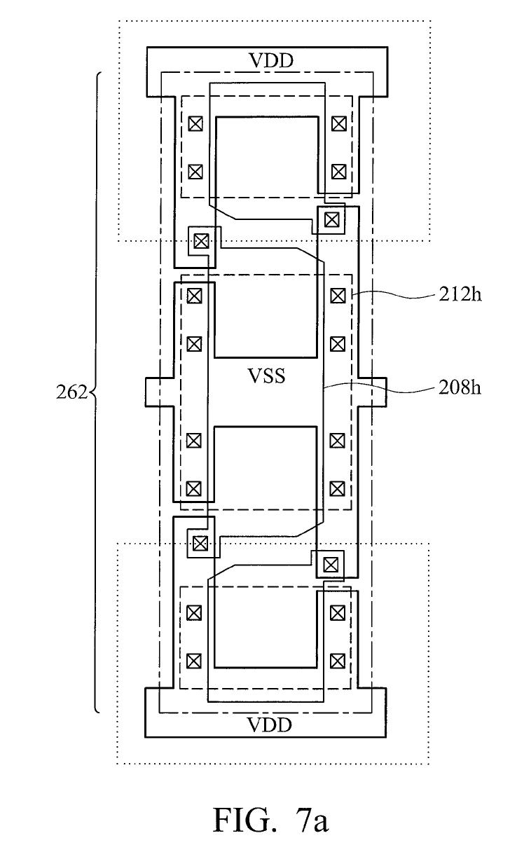

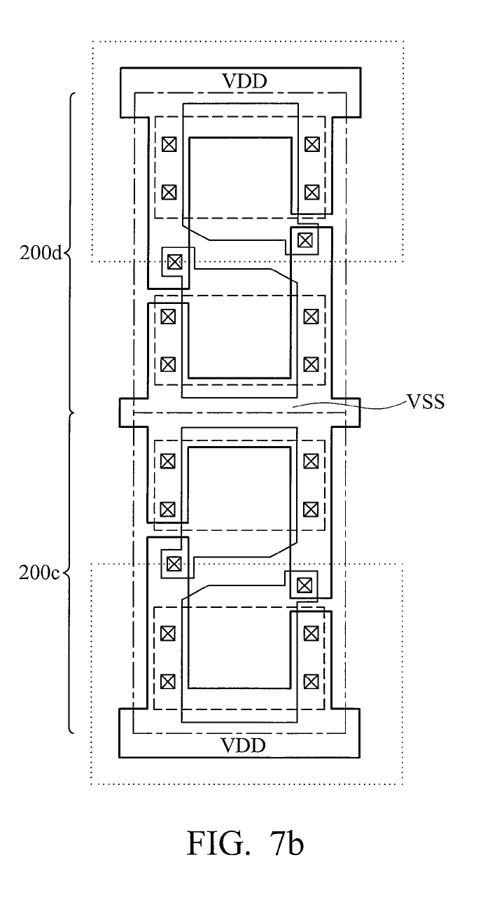

FIG. 7a shows a layout of another double-sized filler capacitor 262 spanning two adjacent cell rows. Three power rails VDD, VSS and VDD extend across double-sized filler capacitor 262, and the middle power rail VSS extends across poly gate 208h and active region 212h. For comparison, FIG. 7b shows two stacked single-sized filler capacitors 200c and 200d having poly gates and active regions substantially separated by the middle power rail VSS. Having extra capacitance provided from the area under the middle power rail, double-sized filler capacitor,262 of FIG. 7a has higher capacitance than the combination of the stacked single-sized filler capacitors 200c and 200d of FIG. 7b.

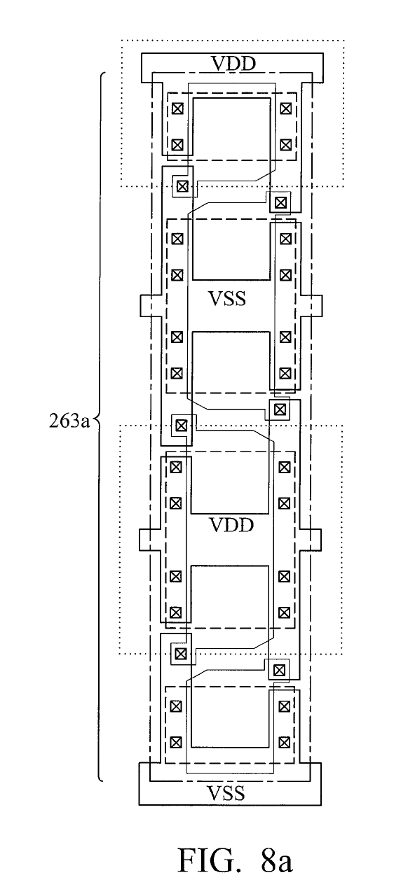

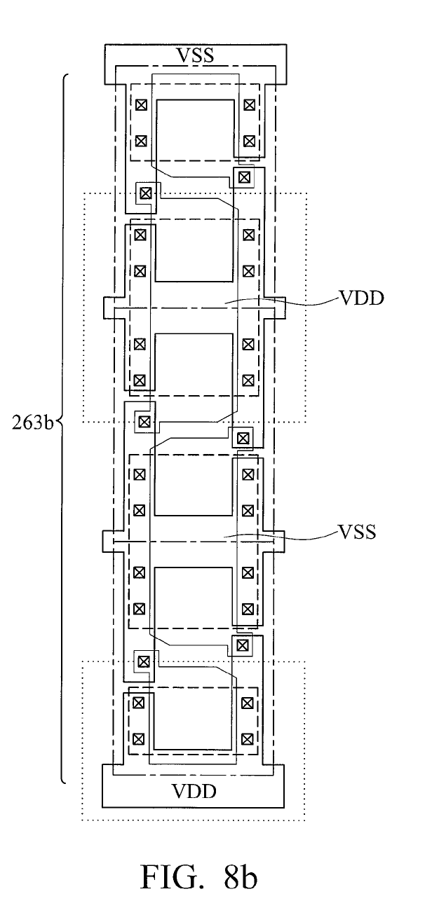

Conversion of a field isolation area under a middle power rail to a portion of a MOS capacitor is also applicable to other kinds of multiple-row filler capacitors, each spanning multiple cell rows. FIGS. 8a and 8b show layouts of two triple-sized filler capacitors 263a and 263b, each spanning three consecutive cell rows. Power rails VDD, VSS, VDD and VSS extend across triple-sized filler capacitors 263a while power rails VSS, VDD, VSS, and VDD extend across triple-sized filler capacitors 263b. Triple-sized filler capacitors 263a and 263b each have higher capacitance than three stacked single-sized filler capacitors (not shown). Other multi-row filler capacitors (not shown) may also be included. For example, a quad-sized filler capacitor (not shown) may be included that is four times the height of a single-sized filler capacitor.

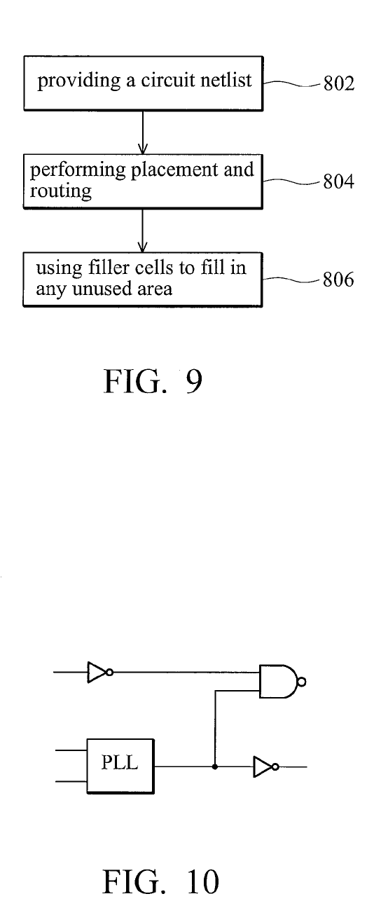

To maximize capacitance provided by filler capacitors, embodiments of the invention also provide a method of forming layout architecture. FIG. 9 is a summarized step flow according to embodiments of the invention. In step 802, a circuit netlist is provided. Based on the circuit netlist, placement and routing are performed to select and place basic cell layouts on a floor plan of an integrated circuit, as shown in step 804. In step 806, unused areas are filled with filler cells.

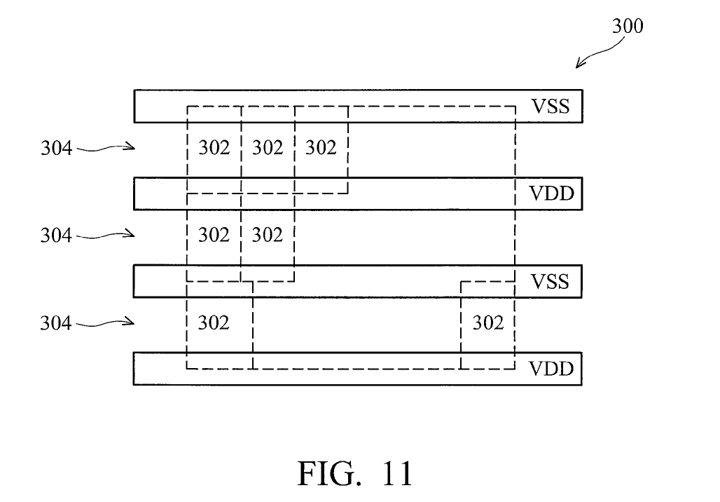

Based on product function requirement and specification of an integrated circuit, a circuit netlist is generated describing the connection between basic cells. FIG. 10 exemplifies a circuit netlist, connecting two NOTs, a NAND and a PLL. Accordingly, electric design automation (EDA) tool performs placement and routing, selecting corresponding basic cell layouts and placing them on a floor plan of the integrated circuit. FIG. 11 shows a floor plan 300 after placement and routing. On floor plan 300, basic cell layouts 302 are arranged into cell rows 304, each powered by two adjacent power rails VDD and VSS. Each power rail, either VDD or VSS, is coupled to power supply VDD or VSS, and extends along one of the rows 304. As shown in FIG. 11, adjacent power rails are coupled to different power voltage supplies. There are several gaps in cell rows 304 not occupied by basic cell layouts 302. These gaps may be separated from each other, or adjoin one another to form an unused area spanning two or more cell rows 304 as shown in FIG. 11.

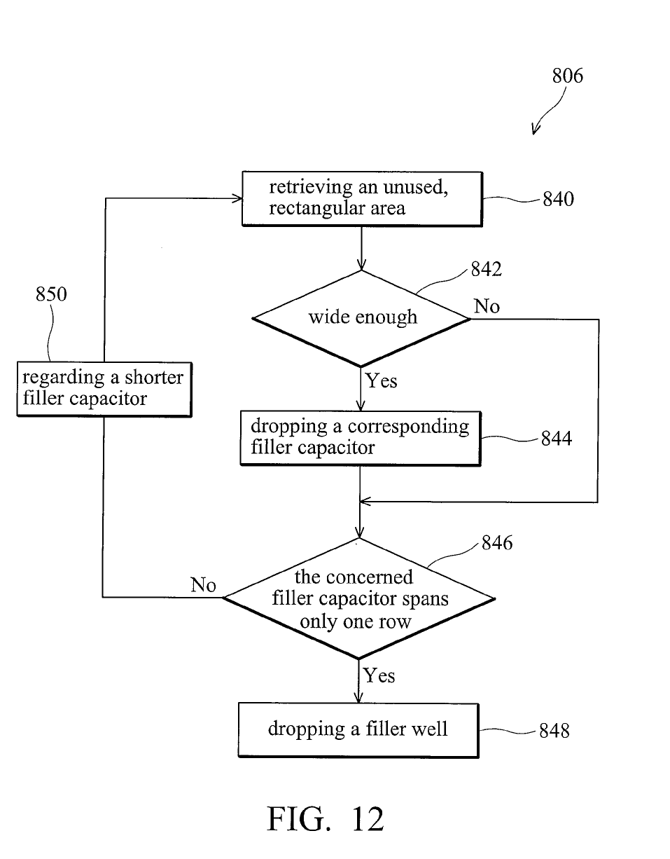

Currently, steps 802 and 804 of FIG. 9 have being performed and the process proceeds to step 806, detailed in FIG. 12 and explained as follows.

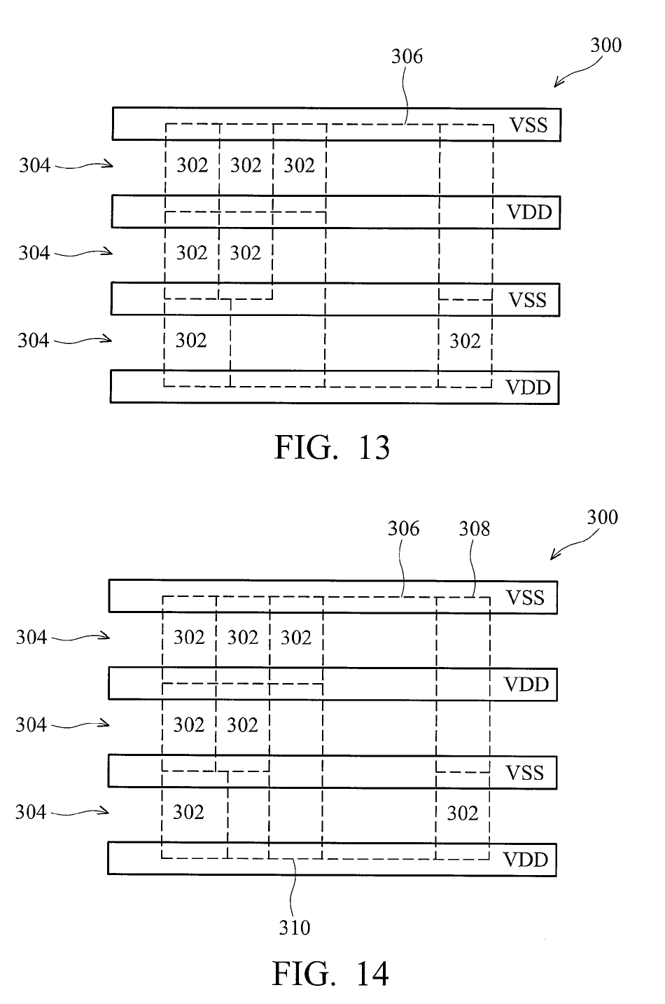

Proceeding to step 840 of FIG. 12, an unused, rectangular area(s) 306 (shown in FIG. 13) spanning the most number of the rows 304 or having the same height of the highest filler capacitor in a cell library is then retrieved from floor plan 300. Although the unused, rectangular area 306 in FIG. 13 spans only three rows 304, the scope of the invention is not limited thereto and a retrieved area may span any number of rows.

The width of the unused rectangular area 306 is then measured in step 842 to determine whether it can accommodate a filler capacitor spanning the same number of cell rows as the unused, rectangular area 306. For example, if the unused rectangular area 306 spans 3 rows under power rails VSS, VDD, VSS and VDD (from top to bottom), it may be suitable for forming the filler capacitor of FIG. 8b if the width of the unused rectangular area 306 exceeds the minimum width required by the filler capacitor of FIG. 8b. If the unused rectangular area 306 is wide enough, step 844 in FIG. 12 is performed and the unused rectangular area 306 receives a corresponding filler capacitor, which may be widened to fulfill the unused rectangular area 306 by elongating only the widths of the poly gates and the active regions therein, increasing the capacitance of the corresponding filler capacitor. The formation of the corresponding filler capacitor also diminishes the unused area.

Whether the unused, rectangular area is used or occupied by a corresponding filler capacitor, steps of retrieving the unused rectangular area, and measuring the, width of the unused rectangular area are further applicable to determine whether a shorter filler capacitor, one row shorter than the filler capacitor discussed, can fill currently unused area(s), a secondary unused area unoccupied by the discussed filler capacitor and the logic cell layouts. In other words, the retrieval, the measurement and the placement form a loop, in FIG. 12 comprising steps 840, 842, 844 and 850. The loop is repeated to determine whether a shorter filler capacitor is applicable for currently unused area(s), as shown by step 850, and diminish the currently unused area(s). Therefore, step 846 in FIG. 12 determines whether the filler capacitor concerned for filling currently unused area spans only one cell row. If so, all currently unused area(s), if any, are too narrow to support a single-sized filler capacitor, the loop is no longer executed, and filler wells are used, as shown in step 848 in FIG. 12.

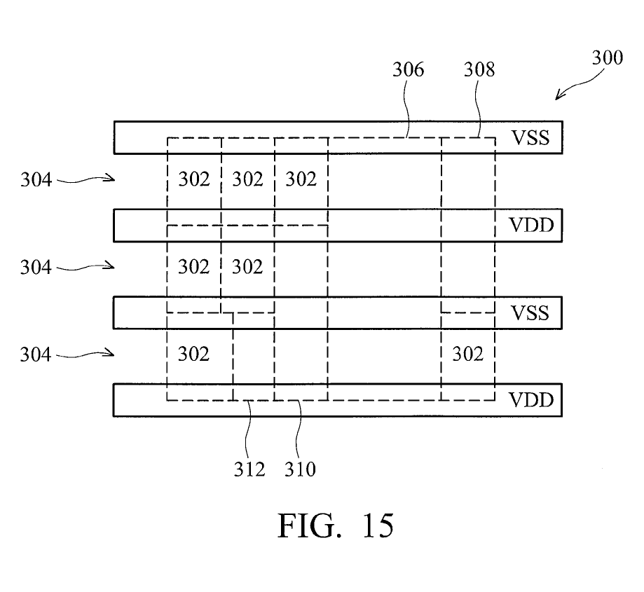

FIG. 14 shows two unused rectangular areas 310 and 308, each spanning two cell rows, retrieved and filled by double-sized filler capacitors after the loop in FIG. 12 is executed the second time. FIG. 15 shows one unused rectangular area 312 spanning with only one cell row height, retrieved and filled by a single-sized filler capacitor or a filler well after the loop in FIG. 12 is executed the third time. FIG. 15 also depicts a digital system of an integrated circuit with layout architecture of single-sized, double-sized and triple-sized filler capacitors.

While the invention has been described by way of examples and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A layout architecture for a standard cell integrated circuit having an array of logic cells, comprising:
a substrate;
a plurality of first power rails above the substrate, each coupled to a power supply and extending across the logic cells, wherein adjacent first power rails are coupled to different voltage supplies; and
a filler capacitor positioned beneath three or more adjacent first power rails and coupled to first and second voltage supplies, wherein the filler capacitor comprises first and second MOS capacitors, the first MOS capacitor is formed with a first gate overlapping a first base in a first active region, the first gate coupled to the first voltage supply and the first base coupled to the second voltage supply, and the second MOS capacitor is formed with a second gate overlapping a second base in a second active region, the second gate coupled to the second voltage supply and a second base coupled to the first voltage supply;
wherein a middle first power rail of the three or more adjacent first power rails extends across one of the first and second active regions.

2. The layout architecture of claim 1, wherein a midpoint of the filler capacitor is under the middle first power rail.

3. The layout architecture of claim 1, wherein the middle first power rail extends across the first active region and is coupled to the second gate.

4. The layout architecture of claim 1, wherein the middle first power rail is coupled to a VDD voltage supply, and the two first power rails adjacent to the middle first power rail are coupled to a VSS voltage supply.

5. The layout architecture of claim 1, wherein the middle first power rail is coupled to a VSS voltage supply, and the two first power rails adjacent to the middle first power rail are coupled to a VDD voltage supply.

6. The layout architecture of claim 1, wherein the array of the logic cells has rows of a fixed height, and the filler capacitor spans a plurality number of the rows.

7. The layout architecture of claim 1, wherein the first MOS capacitor has two source/drains coupled to the second voltage supply, and the second MOS capacitor has two source/drains coupled to the first voltage supply.

8. A digital system comprising an integrated circuit with the layout architecture of claim 1.

9. A method for forming a layout architecture, comprising:
providing a circuit netlist;
performing placement and routing by an electronic design automation tool according to the circuit netlist to place logic cell layouts on a floor plan of an integrated circuit, wherein the logic cell layouts are arranged into cell rows, the floor plan introduces first power rails, each coupled to a power supply and extending along the cell rows and across the logic cell layouts, and adjacent first power rails are coupled to different voltage supplies;
retrieving on the floor plan an unused area, wherein the unused area is unoccupied by the logic cell layouts, spanning two or more of the cell rows, and is under three or more first power rails; and
placing a filler capacitor layout in the unused area, the filler capacitor layout introducing a MOS capacitor formed with a first gate overlapping a first base in a first active region, the first gate coupled to a first voltage supply and the first base coupled to a second voltage supply;
wherein a middle first power rail of the three or more adjacent first power rails extends across the first active region.

10. The method of claim 9, wherein the middle first power rail is coupled to the second voltage supply.

11. The method of claim 9, wherein the filler capacitor comprises first and second MOS capacitors, the first MOS capacitor is formed with the first gate overlapping the first base in the first active region, and the second MOS capacitor is formed with a second gate overlapping a second base in a second active region, the second gate coupled to the second voltage supply and a second base coupled to the first voltage supply.

12. The method of claim 9, wherein the filler capacitor layout spans the two or more cell rows, the method further comprising:
retrieving on the floor plan a secondary unused area, wherein the secondary unused area is unoccupied by the filler capacitor layout and the logic cell layouts, spanning at least one row, and under two or more first power rails; and
placing a secondary filler capacitor layout in the secondary unused area.

13. A layout architecture for a standard cell integrated circuit having an array of logic cells, comprising:
a substrate;
a plurality of first power rails above the substrate, each coupled to a power supply and extending across the logic cells, wherein adjacent first power rails are coupled to different voltage supplies; and
a filler capacitor positioned beneath three or more adjacent first power rails and coupled to first and second voltage supplies, wherein the filler capacitor comprises a first MOS capacitor formed with a first gate overlapping a first base in a first active region, the first gate coupled to the first voltage supply and the first base coupled to the second voltage supply;
wherein a middle first power rail of the three or more adjacent first power rails extends across the first active region.

14. The layout architecture of claim 13, wherein the middle first power rail is coupled to the second voltage supply.

15. The layout architecture of claim 13, wherein the first MOS capacitor has two source/drains coupled to the second voltage supply.

16. The layout architecture of claim 13, wherein the filler capacitor is symmetric with respect to the middle first power rail.
